(19) United States
(12) Patent Application Publication
(10) Pub. No.: US 2007/0153856 A1
(43) Pub. Date: Jul. 5, 2007

(54) SEMICONDUCTOR LASER DEVICE

(75) Inventors: Takeo KAGEYAMA, Tokyo (JP); Yoshihiko Ikenaga, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: THE FURUKAWA ELECTRIC CO., LTD., Tokyo (JP)

(21) Appl. No.: 11/611,500

(22) Filed: Dec. 15, 2006

(30) Foreign Application Priority Data
Dec. 16, 2005 (JP) 2005-363819

(51) Int. Cl. H01S 5/00

(52) U.S. Cl. 372/45.012

(57) ABSTRACT

An active layer is formed by arranging a plurality of quantum-well layers and a plurality of barrier layers alternatively. An amount of band discontinuity in a conduction band between a barrier layer that is sandwiched by the quantum-well layers and adjacent quantum-well layers is equal to or more than 26 meV and less than 300 meV, so that an overflow of injected carriers due to a thermal excitation between the quantum-well layers is intentionally caused to make the carrier density uniform between the quantum-well layers.

### BACKGROUND OF THE INVENTION

1. Field of the Invention

The present invention relates to a technology for reducing a threshold current of a semiconductor laser device that emits a laser light.

2. Description of the Related Art

A conventional semiconductor laser device emits a laser light by amplifying a light generated by a recombination of carriers in an active layer formed with III-V compound semiconductors with an injection of carriers in the active layer. Generally, because the semiconductor laser device has a number of advantages over a gas laser represented by an excimer laser and a solid-state laser represented by a YAG laser, such as compact size and high electrical-optical conversion efficiency, the semiconductor laser device is currently attracting an attention in a variety of industry fields including the optical communications.

One of the semiconductor laser devices used as a light source for an optical communication device emits a laser light in a wavelength band of 1300 nm that offers the minimum optical dispersion in an optical fiber. As the semiconductor laser device that emits the laser light in the wavelength band of 1300 nm, a GaInAsP semiconductor laser device formed on an InP substrate has been proposed. However, the GaInAsP semiconductor laser device has poor temperature characteristics, because a characteristic temperature of the threshold current is in a range of 50K to 70K. To improve the temperature characteristics, a GaInNAs semiconductor laser device has been proposed, in which the characteristic temperature of the threshold current is increased to equal to or higher than 150K by increasing an amount of band offset (i.e., an amount of band discontinuity) in a conduction band between a quantum-well layer and a barrier layer in an active layer to equal to or higher than 350 meV (see, for example, Japanese Patent Application Laid-Open No. 2003-17812).

However, in the semiconductor laser device used as the light source for the optical communication device, a demand for further reducing power consumption for oscillating the laser light is getting higher and higher. Therefore, it is desired to reduce the threshold current within a range of an operation temperature of the semiconductor laser device, particularly near the room temperature, compared to the conventional semiconductor laser device.

### SUMMARY OF THE INVENTION

It is an object of the present invention to at least partially solve the problems in the conventional technology.

A semiconductor laser device according to one aspect of the present invention includes an active layer including a plurality of quantum-well layers and a plurality of barrier layers. The active layer is formed by arranging the quantum-well layers and the barrier layers alternatively. An amount of band discontinuity in a conduction band between a barrier layer that is sandwiched by the quantum-well layers and the quantum-well layers is equal to or more than 26 meV and less than 300 meV.

The above and other objects, features, advantages and technical and industrial significance of this invention will be better understood by reading the following detailed description of presently preferred embodiments of the invention, when considered in connection with the accompanying drawings

### BRIEF DESCRIPTION OF THE DRAWINGS

FIG. 1 is a schematic diagram for explaining a layer structure of a semiconductor laser device according to a first embodiment of the present invention;

FIG. 2 is a schematic diagram for explaining a layer structure of the semiconductor laser device according to the first embodiment near an active layer;

FIG. 3 is a band diagram for explaining an energy level profile of a cladding layer and the active layer in the conduction band, according to the first embodiment;

FIG. 4 is a schematic diagram for explaining a mechanism of uniformizing densities of carriers injected into the active layer between quantum-well layers, according to the first embodiment;

FIG. 5 is a graph of a change of the threshold current with a change of a temperature in an environment for oscillating the laser light;

FIG. 6 is a cross section of a semiconductor laser device according to a modification example of the first embodiment in a direction perpendicular to a light-emitting direction;

FIG. 7 is a band diagram for explaining an energy level profile of an optical-waveguide layer and the active layer in the conduction band, according to the modification example of the first embodiment;

FIG. 8 is a schematic diagram for explaining a layer structure of a semiconductor laser device according to a second embodiment of the present invention;

FIG. 9 is a schematic diagram for explaining a layer structure of the semiconductor laser device according to the second embodiment near an active layer;

FIG. 10 is a band diagram for explaining an energy level profile of a cladding layer and the active layer in the conduction band, according to the second embodiment;

FIG. 11 is a schematic diagram for explaining a mechanism of uniformizing densities of carriers injected into the active layer between quantum-well layers, according to the second embodiment;

FIG. 12 is a cross section of a semiconductor laser device according to a modification example of the second embodiment in a direction perpendicular to a light-emitting direction; and

FIG. 13 is a band diagram for explaining an energy level profile of an optical-waveguide layer and the active layer in the conduction band, according to the modification example of the second embodiment.

### DETAILED DESCRIPTION OF THE PREFERRED EMBODIMENTS

Exemplary embodiments according to the present invention will be explained in detail below with reference to the accompanying drawings. It should be noted that the present invention is not limited exemplary embodiments. The drawings used in the specification are schematics so that a relation between a thickness, a length, and a width of each part and a ratio of thicknesses of respective parts are different from the real ones, and even between the drawings, a part having a different relation or ratio of dimensions may be included.

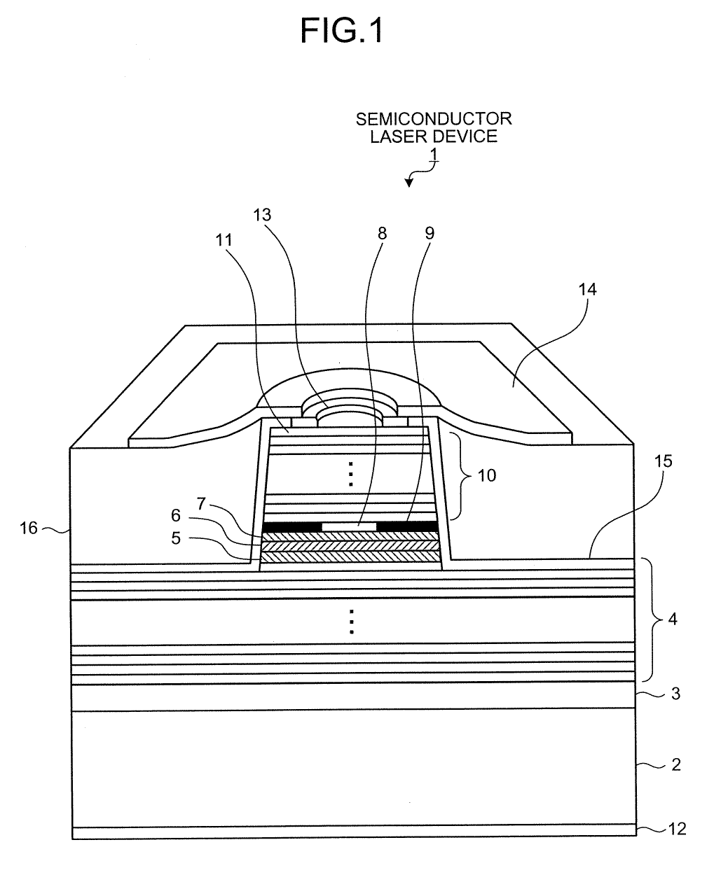

FIG. 1 is a schematic diagram for explaining a layer structure of a semiconductor laser device 1 according to a first embodiment of the present invention. The semiconductor laser device 1 shown in FIG. 1 is a vertical cavity surface emitting laser (VCSEL). FIG. 1 shows an oblique perspective view of a cross section of the semiconductor laser device 1. The semiconductor laser device 1 includes an n-GaAs buffer layer 3, a lower multilayer reflection mirror 4, a cladding layer 5, an active layer 6, a cladding layer 7, a current confinement layer 9 having a current injection path 8, an upper multilayer reflection mirror 10, and a contact layer 11, sequentially grown on an n-GaAs substrate 2. The semiconductor laser device 1 further includes an n-type electrode 12 formed on a bottom of the n-GaAs substrate 2, and a ring-shaped p-type electrode 13 and an electrode pad 14 for drawing the p-type electrode 13 formed on a top of the contact layer 11. A layer area including a top layer of the lower multilayer reflection mirror 4, the cladding layer 5, the active layer 6, the cladding layer 7, the current confinement layer 9, the upper multilayer reflection mirror 10, the contact layer 11, and the p-type electrode 13 is formed in a mesa state. The mesa layer area (mesa post) is covered with a silicon nitride film 15, and a polyimide layer 16 is formed to cover the silicon nitride film 15.

The n-GaAs buffer layer 3 is a buffer layer for relieving a difference of lattice constants between the n-GaAs substrate 2 and the lower multilayer reflection mirror 4. A layer material for the n-GaAs buffer layer 3 includes, for example, an n-GaAs having a carrier density of 1×10¹⁸ cm⁻³.

The lower multilayer reflection mirror 4 and the upper multilayer reflection mirror 10 form a cavity structure sandwiching the cladding layer 5, the active layer 6, and the cladding layer 7. The lower multilayer reflection mirror 4 is formed by depositing, for example, 30 pairs of n-type multilayers consisting of Al_{0.9}Ga_{0.1}As and GaAs. The upper multilayer reflection mirror 10 is formed by depositing, for example, 25 pairs of p-type multilayers consisting of Al_{0.9}Ga_{0.1}As and GaAs.

The cladding layers 5 and 7 are one of those GaAs layers including GaAs as the layer material, and sandwiches the active layer 6 in a direction of the layer thickness. The cladding layers 5 and 7 confine the carriers injected into the active layer 6 in the active layer 6. The active layer 6 is for oscillating a laser light in a predetermined wavelength band (for example, 1300-nm wavelength band) by a recombination of the injected carriers. The active layer 6 includes a plurality of quantum-well layers and a plurality of barrier layers, and is formed by layering the quantum-well layers and the barrier layers alternatively.

The semiconductor laser device 1 having the above layer structure is fabricated by a following method. The n-GaAs buffer layer 3, the lower multilayer reflection mirror 4, the cladding layer 5, the active layer 6, the cladding layer 7, an AlAs layer having a thickness of about 20 nm, the upper multilayer reflection mirror 10, and the contact layer 11 formed by a GaAs are sequentially grown on the n-GaAs substrate 2 by, for example, the metalorganic chemical vapor deposition (MOCVD) method.

After that, a silicon nitride film is deposited on a growth surface of the contact layer 11 by, for example, the plasma chemical vapor deposition (CVD) method, and a circular pattern with a diameter of about 40 micrometers to 45 micrometers is formed on the silicon nitride film by the photolithography technique using a photoresist. The silicon nitride film is etched by the reactive ion etching (RIE) method using a CF4 gas, with the formed circular resist mask. The etching is further processed until it reaches the lower multilayer reflection mirror 4 by the reactive ion-beam etching (RIBE) method using chlorine gas, to form the mesa post. The depth of the etching by the RIBE method is controlled to reach inside the lower multilayer reflection mirror 4.

In the above state, the substrate is heated to 400° C. in a water-vapor atmosphere, and is left as it is, to selectively oxidize the AlAs layer between the cladding layer 7 and the upper multilayer reflection mirror 10. The AlAs layer selectively oxidized in the above manner becomes the current confinement layer 9 in which the current injection path 8 having a diameter of 3 micrometers to 10 micrometers is formed.

Subsequently, the silicon nitride film is completely removed by the RIE method, and the silicon nitride film 15 is now formed by the plasma CVD method. The silicon nitride film 15 covers the mesa post and the top layer of the lower multilayer reflection mirror 4. Then, the polyimide layer 16 is formed on the silicon nitride film 15 except for the top of the mesa post.

The contact layer 11 is exposed by removing the silicon nitride film 15 in a portion formed on the top of the mesa post in a circular shape, and the p-type electrode 13, which is a ring-shaped AuGeNi/Au electrode, is formed on an area where the contact layer 11 is exposed. In addition, the electrode pad 14, which is a Ti/Pt/Au alloy pad for drawing an electrode, is formed on the top of the p-type electrode 13. A dimension of the electrode pad 14 is, for example, about 3,000 μm2. After that, the bottom of the n-GaAs substrate 2 is lapped and polished about 200 micrometers, and the n-type electrode 12, which is an AuGeNi/Au electrode, is deposited on a surface of the polished bottom. Finally, the substrate is annealed at about 400° C. in a nitride atmosphere, and the semiconductor laser device 1 is obtained.

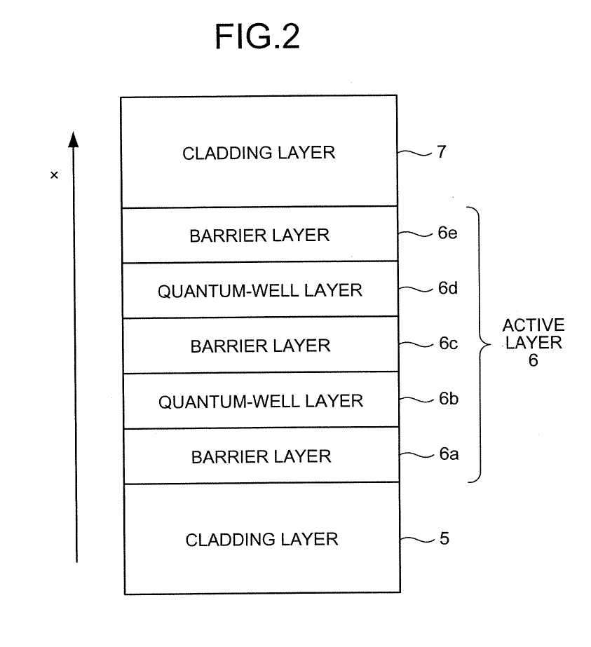

FIG. 2 is a schematic diagram for explaining a layer structure of the semiconductor laser device 1 near the cladding layer 5, the active layer 6, and the cladding layer 7. The layer structure of the semiconductor laser device 1 near the active layer 6 is that the active layer 6 is sandwiched by the cladding layers 5 and 7 in a direction of the layer thickness. The active layer 6 is formed by layering the quantum-well layers and the barrier layers alternatively, including, for example, two quantum-well layers 6b and 6d and three barrier layers 6a, 6c, and 6e, in which the barrier layer 6a, the quantum-well layer 6b, the barrier layer 6c, the quantum-well layer 6d, and the barrier layer 6e are sequentially grown from the cladding layer 5 toward the cladding layer 7. The barrier layers 6a and 6e are outermost barrier layers formed on both ends of the active layer 6 in a direction of the layer thickness, and are adjacent to the cladding layers 5 and 7, respectively. The barrier layer 6c is the one formed in an area sandwiched by the barrier layers 6a and 6e, and is sandwiched by the quantum-well layers 6b and 6d. In other words, the quantum-well layer 6b is sandwiched by the barrier layers 6a and 6c, and the quantum-well layer 6d is sandwiched by the barrier layers 6c and 6e.

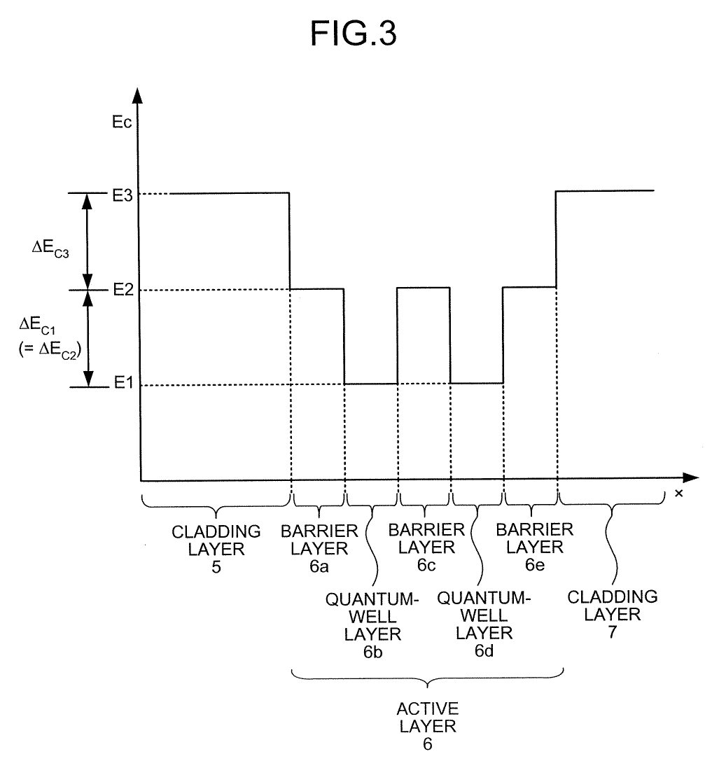

FIG. 3 is a band diagram for explaining an energy level profile of the cladding layer 5, the active layer 6, and the cladding layer 7 in the conduction band. In the band diagram shown in FIG. 3, a direction of the layer thickness from the cladding layer 5 toward the cladding layer 7 is taken as the x-axis (see FIG. 2), and a profile of the energy level E_{c} in the conduction band is shown for a position in the direction of the layer thickness.

The quantum-well layers 6b and 6d confine the injected carrier, and recombines the confined carriers. The quantum-well layers 6b and 6d are uniform layers of compound semiconductors including, for example, GaInNAsSb in the layer materials, and as shown in FIG. 3, an amount of strain, a layer thickness, and a composition of the layer materials are controlled so that the energy level E_{c} (meV) in the conduction band becomes E1. The value E1 is the energy level in the conduction band with which a bandgap capable of oscillating a laser light in, for example, 1300-nm wavelength band can be obtained. In the quantum-well layers 6b and 6d having E1 as the energy level E_{c}, a laser light having an oscillation wavelength in a range of, for example, equal to or more than 1200 nm and equal to or less than 1350 nm is emitted by the recombination of the injected carriers. The quantum-well layers 6b and 6d can also be uniform layers of compound semiconductors including GaInAsSb, or GaInAs in the layer materials, instead of GaInNAsSb.

The barrier layers 6a, 6c, and 6e are for bringing out a carrier confining function in the quantum-well layers 6b and 6d. The barrier layers 6a, 6c, and 6e are uniform layers of compound semiconductors including, for example, GaNAs in the layer materials, and as shown in FIG. 3, an amount of strain, a layer thickness, and a composition of the layer materials are controlled so that the energy level E_{c} (meV) in the conduction band becomes E2. The value E2 is the energy level in the conduction band with which an amount of band discontinuity ΔE_{c2} between the outermost barrier layers 6a and 6e from among the barrier layers 6a, 6c, and 6e and the quantum-well layers 6b and 6d becomes equal to or more than 26 meV and less than 300 meV, and an amount of band discontinuity ΔE_{c1} between the barrier layers 6c and the quantum-well layers 6b and 6d becomes equal to or more than 26 meV and less than 300 meV. The amounts of band discontinuity ΔE_{c1} and ΔE_{c2} are calculated, as shown in FIG. 3, by a difference of the energy levels E_{c}, (E2-E1) between the barrier layers 6a, 6c, and 6e and the quantum-well layers 6b and 6d. The barrier layers 6a, 6c, and 6e satisfying the conditions for the amounts of band discontinuity ΔE_{c1} and ΔE_{c2} can bring out the carrier confining function in the quantum-well layers 6b and 6d, so that a laser light in a predetermined wavelength band (for example, 1300-nm wavelength band) can be emitted, by sandwiching each of the quantum-well layers 6b and 6d. The barrier layers 6a, 6c, and 6e can also be uniform layers of compound semiconductors including GaNAsP, GaInAs, GaInNAs, GaInAsSb, GaInNAsSb, or GaNAsSb in the layer materials, instead of GaNAs.

The cladding layers 5 and 7 are one of those GaAs layers including GaAs in the layer materials, and functions as carrier confining layers that confine the carriers injected into the active layer 6 in the active layer 6. An amount of strain, a layer thickness, and a composition of the layer materials of the cladding layers 5 and 7 are controlled, as shown in FIG. 3, so that the energy level E_{c} (meV) in the conduction band becomes E3. The value E3 is the energy level in the conduction band with which an amount of band discontinuity ΔE_{c3} between the outermost barrier layers 6a and 6e and the cladding layers 5 and 7 becomes equal to or more than 250 meV and equal to or less than 500 meV. The amount of band discontinuity ΔE_{c3} is calculated, as shown in FIG. 3, by a difference of the energy levels EC (E3-E2) between the cladding layers 5 and 7 and the outermost barrier layers 6a and 6e. The cladding layers 5 and 7 satisfying the condition for the amount of band discontinuity ΔE_{c3} can confine the injected carriers in the active layer 6 by sandwiching the active layer 6.

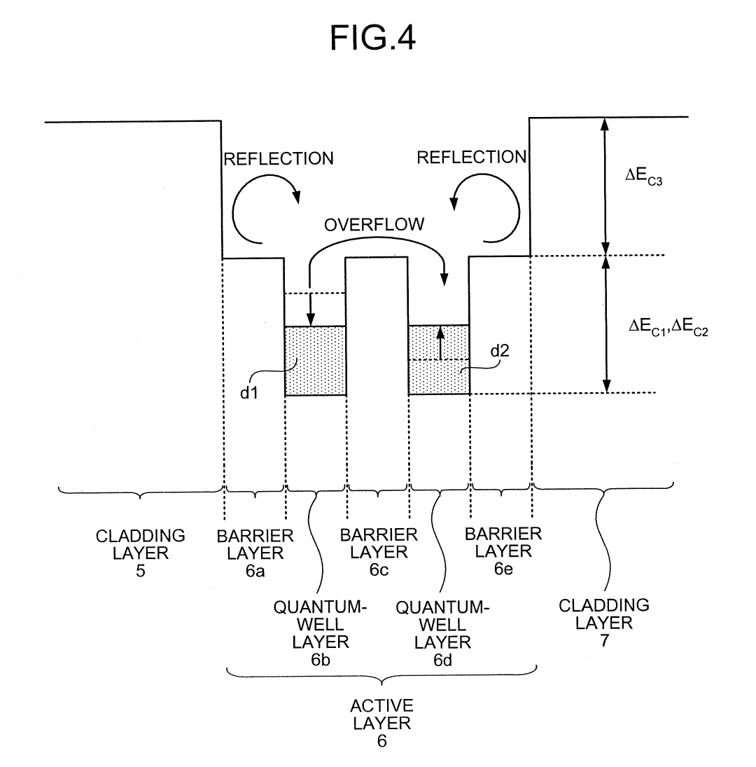

The semiconductor laser device 1 including the active layer 6 that satisfies the conditions for the amounts of band discontinuity ΔE_{c1} and ΔE_{c2} and the cladding layers 5 and 7 that satisfy the condition for the amount of band discontinuity ΔE_{c3} can make a density of the carrier injected into the active layer 6 virtually uniform between the quantum-well layers 6b and 6d. FIG. 4 is a schematic diagram for explaining a mechanism of uniformizing the density of the carrier injected into the active layer 6 between the quantum-well layers 6b and 6d.

When a current is injected into the active layer 6, carriers are injected into the quantum-well layers 6b and 6d, and carrier densities d1 and d2 of the quantum-well layers 6b and 6d are increased, respectively. If the carries are injected uniformly into each of the quantum-well layers 6b and 6d, the carrier densities d1 and d2 are substantially the same, being increased until the current injected into the active layer 6 reaches a threshold current Iₜₕ. However, if the carriers are injected not uniformly into each of the quantum-well layers 6b and 6d, a difference occurs between the carrier densities d1 and d2.

The barrier layer 6c formed between the quantum-well layers 6b and 6d is the one satisfying the condition for the amount of band discontinuity ΔE_{c1} (i.e., 26 meV≦ΔE_{c1} <300 meV).

In general, the two barrier layers sandwiching the quantum-well layer in the direction of the layer thickness can suppress, when the amount of band discontinuity with respect to the quantum-well layer (i.e., the amount of band discontinuity between the quantum-well layer and the barrier layers on both sides in the conduction band) ΔE_{c} is equal to or more than 300 meV, an overflow of the carriers injected into the quantum-well layer to the barrier layer due to a thermal excitation, and confine the carriers in the quantum-well layer for sure. This is because a characteristic temperature T0 of the threshold current Ith is saturated to an ideal value (i.e., a value with which the overflow of the carrier from the quantum-well layer to the barrier layer due to the thermal excitation can be prevented) due to the fact that the amount of band discontinuity ΔE_{c} is equal to or more than 300 meV. In other words, the barrier layer that is sandwiched between the quantum-well layers can prevent, if the amount of band discontinuity with respect to the quantum-well layers on both sides ΔE_{c} is equal to or more than 300 meV, the carrier overflow due to the thermal excitation between the quantum-well layers.

Therefore, in the quantum-well layers 6b and 6d that sandwiches the barrier layer 6c having the amount of band discontinuity ΔE_{c} of less than 300 meV, if the densities of the injected carriers are not uniform (i.e., the carrier density d1 is different from the carrier density d2), the carrier overflow due to the thermal excitation occurs. In this case, the carriers in the quantum-well layers 6b and 6d are excited by a thermal energy, and move from a quantum-well layer having a larger carrier density to a quantum-well layer having a smaller carrier density over the barrier layer 6c. For instance, as shown in FIG. 4, when the carrier density d1 is larger than the carrier density d2, the carriers in the quantum-well layer 6b, which is equivalent to the difference between the carrier densities d1 and d2, cross over the barrier layer 6c (i.e., overflows), and move to the quantum-well layer 6d. In this manner, by the overflow of the carriers due to the thermal excitation, the carrier densities d1 and d2 can be adjusted to the substantially same value, and the carrier densities between the quantum-well layers 6b and 6d can be made virtually uniform.

The lower-limit values of the amounts of the band discontinuities ΔE_{c1} and ΔE_{c2} of the barrier layers 6a, 6c, and 6e are set to 26 meV. This is based on a fact that the operating temperature of the semiconductor laser device 1 (i.e., the temperature of the environment where the laser light is emitted) is higher than the room temperature. In general, a thermal energy of the carrier injected into the quantum-well layer under a condition of the room temperature (for example, 27° C.) is about 26 meV. Therefore, if the amount of band discontinuity ΔE_{c} between the quantum-well layer and the barrier layer in the conduction band is set below 26 meV, the carriers injected into the quantum-well layer easily overflows from the quantum-well layer to the barrier layer under a condition of the operating temperature higher than the room temperature. The quantum-well layer from which the carriers overflow to the barrier layer cannot contribute to the optical gain, which will cause the laser oscillation operation of the semiconductor laser device not to be performed normally. For this reason, the lower-limit values of the amounts of band discontinuity ΔE_{c1} and ΔE_{c2} of the barrier layers 6a, 6c, and 6e are set to 26 meV. The quantum-well layers 6b and 6d sandwiched by such barrier layers 6a, 6c, and 6e can function as the one that can bring out an effect of confining the injected carriers, and can emit a laser light by confining the carriers injected under a condition of the operating temperature higher than the room temperature.

The cladding layers 5 and 7 are the one satisfying the condition for the amount of band discontinuity ΔE_{c3}(i.e., 250 meV≦ΔE_{c3}≦500 meV) The outermost barrier layers 6a and 6e are, similar to the barrier layer 6c, the one satisfying the condition for the amount of band discontinuity ΔE_{c2} with respect to the quantum-well layers 6b and 6d, which is equal to or more than 26 meV and less than 300 meV. Therefore, the carriers in the quantum-well layers 6b and 6d may overflow to the barrier layers 6a and 6e due to the thermal excitation. However, because the amount of band discontinuity ΔE_{c3} of the cladding layers 5 and 7 satisfies the condition of being equal to or more than 250 meV and equal to or less than 500 meV, the cladding layers 5 and 7 can reflect the carriers overflowed from the quantum-well layers 6b and 6d to the outermost barrier layers 6a and 6e toward the quantum-well layers 6b and 6d. Therefore, the cladding layers 5 and 7 that satisfy the condition for the amount of band discontinuity ΔE_{c3} can confine the carriers injected into the quantum-well layers 6b and 6d in the quantum-well layers 6b and 6d for sure.

The semiconductor laser device can generally lower the threshold current Iₜₕ by adopting a multiple quantum-well structure having a plurality of quantum-well layers, compared to the one with a single quantum-well structure having a single quantum-well layer. However, if densities of the carriers injected into the active layer are not uniform between the quantum-well layers, the semiconductor laser device having a plurality of quantum-well layers can hardly lower the threshold current Iₜₕ. This is because some of the quantum-well layers cannot contribute to the optical gain due to the nonuniformity of the carrier densities between the quantum-well layers.

On the other hand, the semiconductor laser device 1 according to the first embodiment includes the active layer 6 formed with the quantum-well layers 6b and 6d and the barrier layers 6a, 6c, and 6e that satisfy the conditions for the amounts of band discontinuity ΔE_{c1} and ΔE_{c2}, and the cladding layers 5 and 7 that satisfy the condition for the amount of band discontinuity ΔE_{c3}; and therefore, the semiconductor laser device 1 can confine the injected carriers in the active layer 6 for sure, and make the carrier densities uniform between the quantum-well layers 6b and 6d, which can lower the threshold current Iₜₕ.

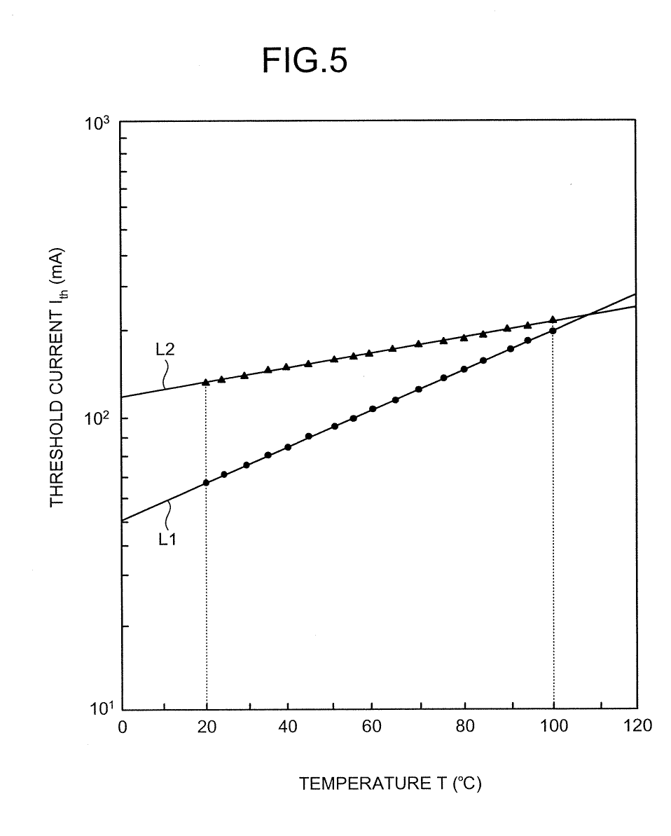

The mechanism for lowering the threshold current Iₜₕ of the semiconductor laser device 1 will be explained in detail below. A sample of the semiconductor laser device 1 including the active layer 6 that is formed with the quantum-well layers 6b and 6d and the barrier layers 6a, 6c, and 6e described above is fabricated, and data of the threshold current Iₜₕ is obtained using the fabricated sample under a condition of temperature equal to or higher than 20° C. and equal to or lower than 100° C. FIG. 5 is a graph of a change of the threshold current Iₜₕ with a change of a temperature T in an environment the semiconductor laser device emits a laser light. In the graph shown in FIG. 5, a relation between the temperature T and the threshold current Iₜₕ of the semiconductor laser device 1 is indicated by a line L1, and a relation between the temperature T and the threshold current Iₜₕ of a comparison sample to be compared with the semiconductor laser device 1 is indicated by a line L2. The comparison sample has a virtually same structure as the semiconductor laser device 1 except for a barrier layer that has the amounts of band discontinuity ΔE_{c1} and ΔE_{c2} of equal to or more than 350 meV, instead of the barrier layers 6a, 6c, and 6e.

As shown in FIG. 5, a comparison of the threshold current Iₜₕ corresponding to the temperature T in a range of equal to or higher than 20° C. and equal to or lower than 100° C. shows that the threshold current indicated by the line L1 is lower than the threshold current indicated by the line L2. From this result of the comparison, it is clear that the semiconductor laser device 1 can lower the threshold current Iₜₕ at the temperature of equal to or lower than 100° C., more particularly, at the operating temperature near the room temperature, compared to the comparison sample, which will allow the semiconductor laser device 1 to increase the quantum efficiency.

From a result of investigating the characteristics of the semiconductor laser device 1, a transparent threshold current density per quantum-well layer (kA/cm/well) at the temperature of 20° C. is as low as 0.11 to 0.13. The transparent threshold current density is obtained by taking off a parameter relating to the cavity, such as a cavity length, from a value obtained by dividing the threshold current Iₜₕ by an effective current area of the active region (threshold current density). In other words, the semiconductor laser device 1 can lower the transparent threshold current density, and increase the quantum efficiency compared to the conventional semiconductor laser device.

Furthermore, the characteristic temperature T₀ (K) of the threshold current Iₜₕ at a temperature range between 25° C. and 85° C. is as high as 80 to 100. The characteristic temperature T0 of the semiconductor laser device 1 is lower than that of the comparison sample, as can be expected from slopes of the lines L1 and L2 shown in FIG. 5. However, the absolute value of the characteristic temperature T₀ (K) (about 80 to 100) of the semiconductor laser device 1 is large enough compared to the characteristic temperature of a GaInAsP semiconductor laser device fabricated on an InP substrate (i.e., the conventional semiconductor laser device) (50K to 70K), and will not cause any particular problem in terms of the temperature characteristics.

As described above, according to the first embodiment, the active layer of the semiconductor laser device is formed with a plurality of quantum-well layers and at least one barrier layer, by forming the quantum-well layers and the barrier layers alternatively. The amount of band discontinuity ΔE_{c2} between the barrier layer sandwiched by the quantum-well layers from among the barrier layers and the quantum-well layers in the conduction band is set to equal to or more than 26 meV and less than 300 meV. With this structure, when densities of the carriers injected into the quantum-well layers are not uniform between the quantum-well layers, it is possible to intentionally cause an overflow of the carriers due to the thermal excitation between the quantum-well layers, and to make the carrier density uniform between the quantum-well layers. Therefore, all of the quantum-well layers in the active layer can contribute to the optical gain, which will make it possible to realize the semiconductor laser device that can lower the threshold current in a temperature range of equal to or lower than 100° C., more particularly, at the operating temperature near the room temperature.

In addition, the semiconductor laser device further includes the cladding layers that sandwiches the active layer in the direction of the layer thickness, and the amount of band discontinuity between the cladding layers and the outermost barrier layers is set to equal to or more than 250 meV and equal to or less than 500 meV. With this structure, the cladding layers can reflect the carriers overflowed from the quantum-well layers to the outermost barrier layers toward the quantum-well layers, which makes it possible to confine the carriers injected into the active layer in the active layer for sure.

By employing a layer structure in which the active layer formed by arranging the quantum-well layers and the barrier layers satisfying the conditions of the amounts of band discontinuity in the conduction band, it is possible to realize a VCSEL that can emit a laser light of an oscillation wavelength, for example, in 1300-nm wavelength band, and lower the threshold current in a temperature range of equal to or lower than 100° C., more particularly, at the operating temperature near the room temperature.

A modification example of the first embodiment will be explained below. Although the semiconductor laser device 1 described in the first embodiment is a VCSEL, the present invention is not limited to the VCSEL. A semiconductor laser device according to the modification example of the first embodiment is an edge-emitting semiconductor laser device.

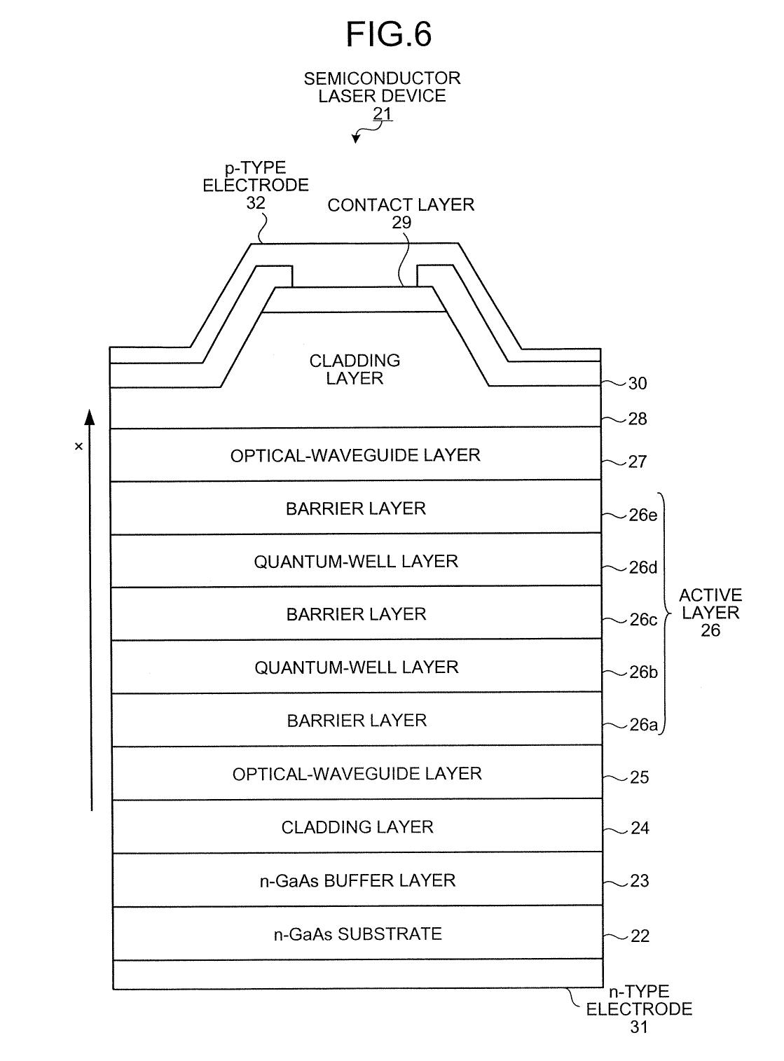

FIG. 6 is a cross section of a semiconductor laser device 21 according to the modification example of the first embodiment in a direction perpendicular to a light-emitting direction. The semiconductor laser device 21 is a ridge waveguide type having a Fabry-Perot cavity structure with a multiple quantum-well separate-confinement heterostructure (MQW-SCH).

As shown in FIG. 6, the semiconductor laser device 21 includes an n-GaAs buffer layer 23, a cladding layer 24, an optical-waveguide layer 25, an active layer 26, an optical-waveguide layer 27, a cladding layer 28, and a contact layer 29, sequentially grown on an n-GaAs substrate 22. In the semiconductor laser device 21, a silicon nitride film 30 is formed to cover an area that is a top area of the cladding layer 28 except for a deposition area of the contact layer 29 and a periphery of the contact layer 29, a p-type electrode 32 is formed on a top of the contact layer 29, and an n-type electrode 31 is formed on a bottom of the n-GaAs substrate 22.

The n-GaAs buffer layer 23 is a buffer layer for relieving a difference of lattice constants between the n-GaAs substrate 22 and the cladding layer 24. A layer material for the n-GaAs buffer layer 23 includes, for example, an n-GaAs having a carrier density of 1×10¹⁸ cm⁻³.

The cladding layers 24 and 28 confine the laser light generated by the recombination of the carriers in the active layer 26. The cladding layers 24 and 28 include a material having a lower refractive index that those of the optical-waveguide layers 25 and 27 and the active layer 26, for example, a compound semiconductor such as AlGaAs and InGaP in the layer materials.

The optical-waveguide layers 25 and 27 are one of those GaAs layers including GaAs in the layer materials, and sandwich the active layer 26 in the direction of the layer thickness. The optical-waveguide layers 25 and 27 can confine the carriers in the active layer 26, and function as waveguides for the laser light generated by the recombination of the carriers in the active layer 26.

The active layer 26 is for oscillating a laser light in a predetermined wavelength band (for example, 1300-nm wavelength band) by the recombination of the injected carriers. The active layer 6 includes a plurality of quantum-well layers and a plurality of barrier layers, and is formed by layering the quantum-well layers and the barrier layers alternatively. Specifically, the active layer 26 includes, as shown in FIG. 6, two quantum-well layers 26b and 26d and three barrier layers 26a, 26c, and 26e, in which the barrier layer 26a, the quantum-well layer 26b, the barrier layer 26c, the quantum-well layer 26d, and the barrier layer 6e are sequentially grown from the optical-waveguide layer 25 toward the optical-waveguide layer 27. The barrier layers 26a and 26e are outermost barrier layers formed on both ends of the active layer 26 in the direction of the layer thickness, and are adjacent to the optical-waveguide layers 25 and 27, respectively. The barrier layer 26c is the one formed in an area sandwiched by the barrier layers 26a and 26e, and is sandwiched by the quantum-well layers 26b and 26d. In other words, the quantum-well layer 26b is sandwiched by the barrier layers 26a and 26c, and the quantum-well layer 26d is sandwiched by the barrier layers 26c and 26e.

The semiconductor laser device 21 having the above layer structure is fabricated by a following method. The n-GaAs buffer layer 23, the cladding layer 24, the optical-waveguide layer 25, the active layer 26, the optical-waveguide layer 27, the cladding layer 28, and the contact layer 29 in which a p-type impurity such as a zinc is doped are sequentially grown on the n-GaAs substrate 22 by, for example, the MOCVD method. The cladding layer 28 of a ridge structure having the contact layer 29 on the top is formed by etching a part of the cladding layer 28 and the contact layer 29 by using known photolithography and etching techniques on the cladding layer 28 on which the contact layer 29 is formed. After that, the silicon nitride film 30 that is an insulating material is deposited on the top of the cladding layer 28 and the contact layer 29 of the ridge structure by, for example, the plasma CVD method, and the contact layer 29 is exposed by etching an area inside the periphery of the contact layer 29, which is a part of the silicon nitride film 30.

Subsequently, the p-type electrode 32, which is a AuGeNi/Au electrode, is formed on the top of the contact layer 29, which is exposed through a window of the silicon nitride film 30, by, for example, a deposition method. The bottom of the n-GaAs substrate 22 is lapped and polished, and the n-type electrode 31, which is an AuGeNi/Au electrode, is deposited on a surface of the polished bottom.

After that, the substrate on which the above layers including the active layer 26 is cleaved into a predetermined cavity length (for example, about 1000 micrometers), a surface protection film and a low-reflection film are sequentially formed on the exposed cleaved facet, and a high-reflection film is formed on the other side of the facet. In this manner, the semiconductor laser device 21 is obtained.

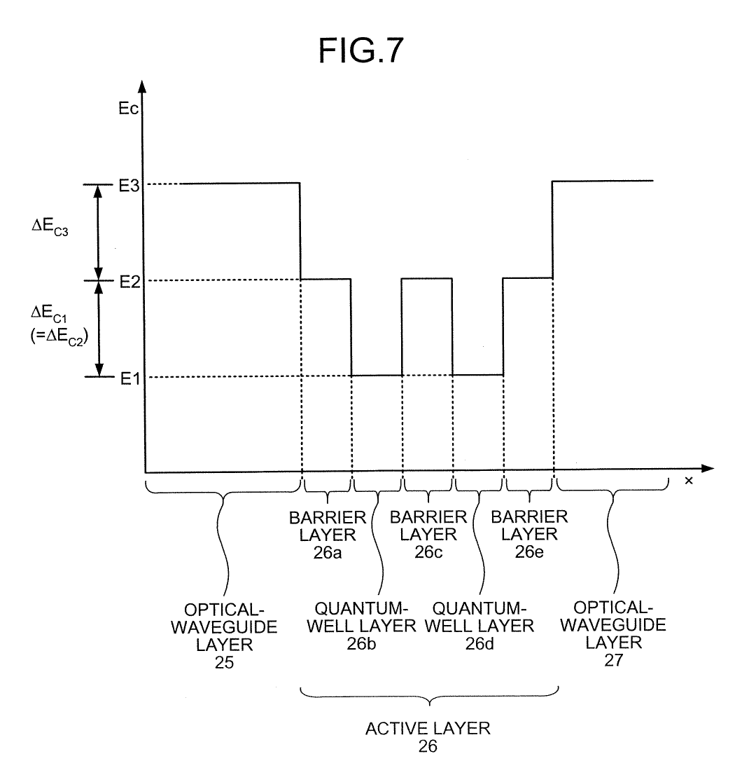

FIG. 7 is a band diagram for explaining an energy level profile of the optical-waveguide layers 25 and 27 and the active layer 26 in the conduction band. In the band diagram shown in FIG. 7, the direction of the layer thickness from the optical-waveguide layer 25 toward the optical-waveguide layer 27 is taken as the x-axis (see FIG. 6), and a profile of the energy level E_{c} in the conduction band is shown for a position in the direction of the layer thickness.

The quantum-well layers 26b and 26d confine the injected carrier, and recombines the confined carriers. The quantum-well layers 26b and 26d are uniform layers of compound semiconductors including, for example, GaInNAsSb in the layer materials, and as shown in FIG. 7, an amount of strain, a layer thickness, and a composition of the layer materials are controlled so that the energy level E_{c} (meV) in the conduction band becomes E1. In the quantum-well layers 6b and 6d having E1 as the energy level E_{c}, a laser light having an oscillation wavelength in a range of, for example, equal to or more than 1200 nm and equal to or less than 1350 nm is emitted by the recombination of the injected carriers. The quantum-well layers 26b and 26d can also be uniform layers of compound semiconductors including GaInAsSb, or GaInAs in the layer materials, instead of GaInNAsSb.

The barrier layers 26a, 26c, and 26e are for bringing out a carrier confining function in the quantum-well layers 26b and 26d. The barrier layers 26a, 26c, and 26e are uniform layers of compound semiconductors including, for example, GaNAs in the layer materials, and as shown in FIG. 7, an amount of strain, a layer thickness, and a composition of the layer materials are controlled so that the energy level E_{c} (meV) in the conduction band becomes E2. In this case, an amount of band discontinuity ΔE_{c2} between the outermost barrier layers 26a and 26e and the quantum-well layers 26b and 26d becomes equal to or more than 26 meV and less than 300 meV, and an amount of band discontinuity ΔE_{c1} between the barrier layers 26c and the quantum-well layers 26b and 26d becomes equal to or more than 26 meV and less than 300 meV. The barrier layers 26a, 26c, and 26e satisfying the conditions for the amounts of band discontinuity ΔE_{c1} and ΔE_{c2} can bring out the carrier confining function in the quantum-well layers 26b and 26d, so that a laser light in a predetermined wavelength band (for example, 1300-nm wavelength band) can be emitted, by sandwiching each of the quantum-well layers 26b and 26d. The barrier layers 26a, 26c, and 26e can also be uniform layers of compound semiconductors including GaNAsP, GaInAs, GaInNAs, GaInAsSb, GaInNAsSb, or GaNAsSb in the layer materials, instead of GaNAs.

The optical-waveguide layers 25 and 27 are one of those GaAs layers including GaAs in the layer materials, and functions as carrier confining layers that confine the carriers injected into the active layer 26 in the active layer 26. An amount of strain, a layer thickness, and a composition of the layer materials of the optical-waveguide layers 25 and 27 are controlled, as shown in FIG. 7, so that the energy level E_{c} (meV) in the conduction band becomes E3. In this case an amount of band discontinuity ΔE_{c3} between the outermost barrier layers 26a and 26e and the optical-waveguide layers 25 and 27 becomes equal to or more than 250 meV and equal to or less than 500 meV. The optical-waveguide layers 25 and 27 satisfying the condition for the amount of band discontinuity ΔE₃ can confine the injected carriers in the active layer 26 by sandwiching the active layer 26.

Comparing FIG. 3 and FIG. 7, the profile of the energy level E_{c} of the semiconductor laser device 21 near the active layer 26, i.e., the energy level profile of the optical-waveguide layers 25 and 27 and the active layer 26 shown in FIG. 7 is virtually the same as that near the active layer 6 of the semiconductor laser device 1 according to the first embodiment. The profile of the energy level E_{c} near the active layer 26 is the one in which the cladding layers 5 and 7 shown in FIG. 3 are replaced by the optical-waveguide layers 25 and 27, the barrier layers 6a, 6c, and 6e shown in FIG. 3 are replaced by the barrier layers 26a, 26c, and 26e, and the quantum-well layers 6b and 6d shown in FIG. 3 are replaced by the quantum-well layers 26b and 26d.

Therefore, the semiconductor laser device 21 that has the above profile of the energy level E_{c} includes, as in the case of the semiconductor laser device 1 according to the first embodiment, the active layer 26 that is formed with the quantum-well layers 26b and 26d and the barrier layers 26a, 26c, and 26e satisfying the conditions for the amounts of band discontinuity ΔE_{c1} and ΔE_{c2} and the optical-waveguide layers 25 and 27 satisfying the condition for the amount of band discontinuity ΔE_{c3}. Therefore, the semiconductor laser device 21 can confine the injected carriers in the active layer 26 for sure, make the carrier density uniform between the quantum-well layers 26b and 26d, and lower the threshold current Iₜₕ at the temperature of equal to or lower than 100° C., more particularly, at the operating temperature near the room temperature.

From a result of investigating the characteristics of the semiconductor laser device 21, a transparent threshold current density per quantum-well layer (kA/cm/well) at the temperature of 20° C. is as low as 0.11 to 0.13. In other words, the semiconductor laser device 21 can lower the transparent threshold current density, and increase the quantum efficiency compared to the conventional semiconductor laser device.

Furthermore, the characteristic temperature T₀ (K) of the threshold current Iₜₕ at a temperature range between 25° C. and 85° C. is as high as 80 to 100. The absolute value of the characteristic temperature T₀ (K) (about 80 to 100) of the semiconductor laser device 21 is large enough compared to the characteristic temperature of a GaInAsP semiconductor laser device fabricated on an InP substrate (i.e., the conventional semiconductor laser device) (50K to 70K), and will not cause any particular problem in terms of the temperature characteristics.

As describe above, according to the modification example of the first embodiment, because the energy level profile in the conduction band in an area near the active layer, i.e., a layer area where the active layer is sandwiched by two optical-waveguide layers, is set to virtually the same as that near the active layer according to the first embodiment, it is possible to realize an edge-emitting semiconductor laser device having the same effect as the first embodiment.

By employing a layer structure in which the active layer formed by arranging the quantum-well layers and the barrier layers satisfying the conditions of the amounts of band discontinuity in the conduction band, it is possible to emit a laser light, for example, in 1300-nm wavelength band, and lower the threshold current in a temperature range of equal to or lower than 100° C., more particularly, at the operating temperature near the room temperature.

According to the first embodiment, the amount of band discontinuity ΔE_{c2} between the outermost barrier layers 6a and 6e and the quantum-well layers 6b and 6d is set to the same value as the amount of band discontinuity ΔE_{c1} between the barrier layer 6c and the quantum-well layers 6b and 6d. However, according to a second embodiment of the present invention, the amount of band discontinuity ΔE_{c2} between the outermost barrier layers and the quantum-well layers is set to equal to or more than 300 meV, to suppress the overflow of the carriers to the outermost barrier layers.

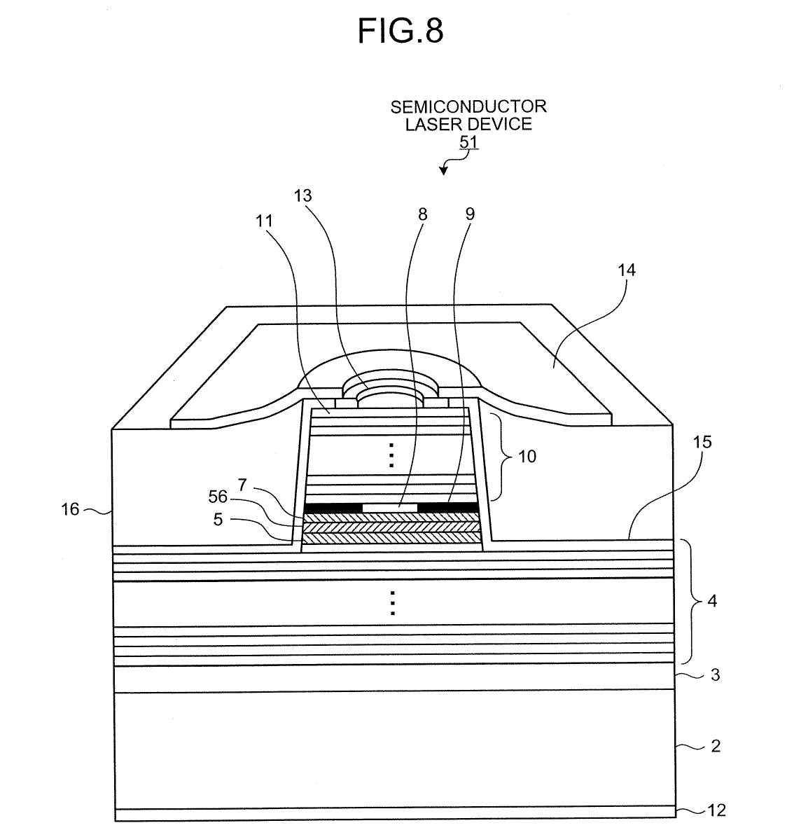

FIG. 8 is a schematic diagram for explaining a layer structure of a semiconductor laser device 51 according to the second embodiment. FIG. 8 shows an oblique perspective view of a cross section of the semiconductor laser device 51. The semiconductor laser device 51 has the same structure as the semiconductor laser device 1 according to the first embodiment, including an active layer 56 instead of the active layer 6 of the semiconductor laser device 1, and the same reference numerals are allocated to the same component parts.

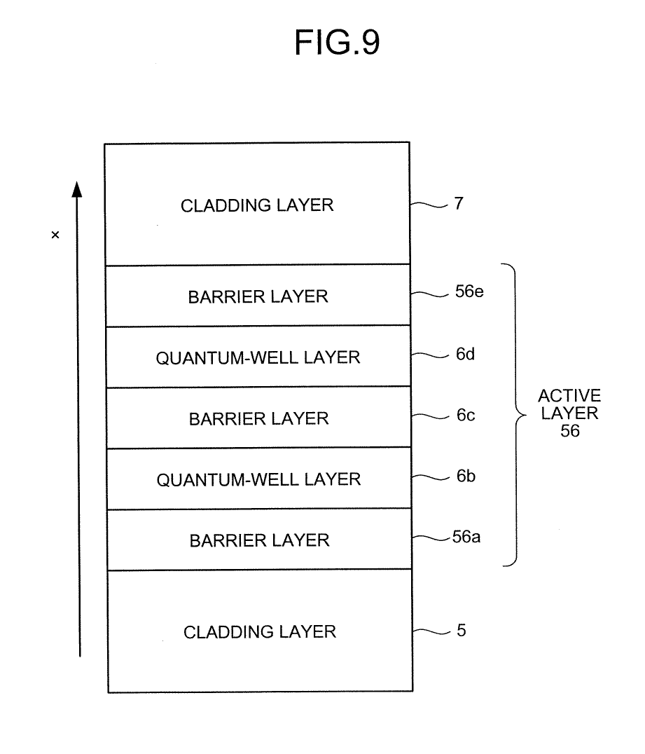

FIG. 9 is a schematic diagram for explaining a layer structure of the semiconductor laser device 51 near the active layer 56. As shown in FIG. 9, the active layer 56 includes outermost barrier layers 56a and 56e instead of the outermost barrier layers 6a and 6e of the active layer 6 according to the first embodiment. Other structures are the same as those of the first embodiment, and the same reference numerals are allocated to the same component parts.

The barrier layers 56a and 56e confine the carriers injected into the active layer 56 in the quantum-well layers 6b and 6d, and suppresses an overflow of the carriers from the quantum-well layers 6b and 6d to the barrier layers 56a and 56e. The barrier layers 56a and 56e are the outermost barrier layers formed on both ends of the active layer 56 in the direction of the layer thickness, and are adjacent to the cladding layers 5 and 7, respectively. The barrier layers 56a and 56e are realized by, for example, uniform layers of compound semiconductors including GaNAs in the layer materials. The barrier layers 56a, 6c, and 56e can also be uniform layers of compound semiconductors including GaNAsP, GaInAs, GaInNAs, GaInAsSb, GaInNAsSb, or GaNAsSb in the layer materials, instead of GaNAs.

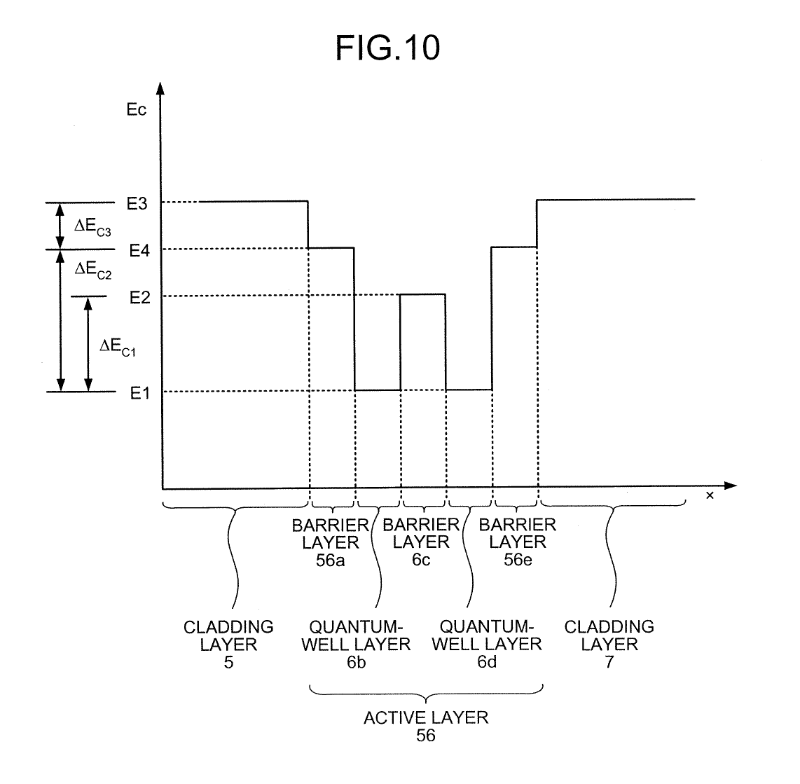

FIG. 10 is a band diagram for explaining an energy level profile of the cladding layers 5 and 7 and the active layer 56 in the conduction band. In the band diagram shown in FIG. 10, the direction of the layer thickness from the cladding layer 5 toward the cladding layer 7 is taken as the x-axis (see FIG. 9), and a profile of the energy level E_{c} in the conduction band is shown for a position in the direction of the layer thickness.

As shown in FIG. 10, an amount of strain, a layer thickness, and a composition of the layer materials of the barrier layers 56a and 56e are controlled so that the energy level E_{c} (meV) in the conduction band becomes E4. The value E4 is the energy level in the conduction band with which an amount of band discontinuity ΔE_{c2} between the outermost barrier layers 56a and 56e from among the barrier layers 56a, 6c, and 56e and the quantum-well layers 6b and 6d becomes equal to or more than 300 meV. The amount of band discontinuity ΔE_{c2} is calculated, as shown in FIG. 10, by a difference of the energy levels E_{c} (E4-E1) between the barrier layers 56a, and 56e and the quantum-well layers 6b and 6d. The barrier layers 56a, and 56e satisfying the condition for the amount of band discontinuity ΔE_{c2} can bring out the carrier confining function in the quantum-well layers 6b and 6d, and suppress the overflow of the carriers from the quantum-well layers 6b and 6d to the barrier layers 56a and 56e.

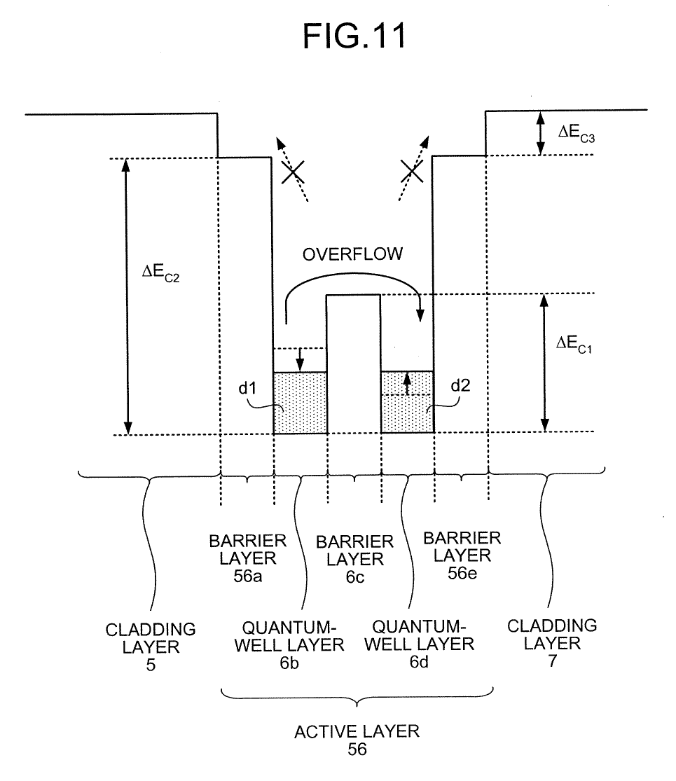

FIG. 11 is a schematic diagram for explaining a mechanism of uniformizing densities of carriers injected into the active layer 56 between the quantum-well layers 6b and 6d. When a current is injected into the active layer 56, carriers are injected into the quantum-well layers 6b and 6d, and carrier densities d1 and d2 of the quantum-well layers 6b and 6d are increased, respectively. If the carries are injected uniformly into each of the quantum-well layers 6b and 6d, the carrier densities d1 and d2 are substantially the same, being increased until the current injected into the active layer 56 reaches a threshold current Ith. However, if the carriers are injected not uniformly into each of the quantum-well layers 6b and 6d, a difference occurs between the carrier densities d1 and d2.

In the quantum-well layers 6b and 6d that sandwiches the barrier layer 6c having the amount of band discontinuity ΔE_{c1} of equal to or more than 26 meV and less than 300 meV, as described above, if the densities of the injected carriers are not uniform (i.e., the carrier density d1 is different from the carrier density d2), the carrier overflow due to the thermal excitation occurs. By the overflow of the carriers due to the thermal excitation, the carrier densities d1 and d2 can be adjusted to the substantially same value, and the carrier densities between the quantum-well layers 6b and 6d can be made virtually uniform.

On the other hand, the outermost barrier layers 56a and 56e are the one satisfying the condition that the amount of band discontinuity ΔE_{c2} is equal to or more than 300 meV. Therefore, the outermost barrier layers 56a and 56e can suppress the overflow of the carriers from the quantum-well layers 6b and 6d to the barrier layers 56a and 56e, and confine the carriers injected into the active layer 56 in the quantum-well layers 6b and 6d for sure.

An amount of band discontinuity ΔE_{c3} between the cladding layers 5 and 7 and the barrier layers 56a and 56e of the semiconductor laser device 51 according to the second embodiment can be a value with which the carriers can be injected into the active layer 56, preferably to be equal to or more than 26 meV. In this case, it is desired that the amount of band discontinuity ΔE_{c2} between the barrier layers 56a and 56e and the quantum-well layers 6b and 6d and the amount of band discontinuity ΔE_{c3} between the cladding layers 5 and 7 and the barrier layers 56a and 56e satisfy a condition that a some of the ΔE_{c2} and the ΔE_{c3} (ΔE_{c2}+ΔE_{c3}) is less than 800 mev. With this condition, the difference of the energy level E_{c} between the quantum-well layers 6b and 6d and the cladding layers 5 and 7 can be set to the same value as the case in the first embodiment.

The semiconductor laser device 51 employing the above structure can make the density of the carriers injected into the active layer 56 uniform between the quantum-well layers 6b and 6d, in the virtually same way as the semiconductor laser device 1 according to the first embodiment, and confine the carriers injected into the active layer 56 in the quantum-well layers 6b and 6d for sure, which makes it possible to lower the threshold current Iₜₕ at the temperature of equal to or lower than 100° C., more particularly, at the operating temperature near the room temperature.

From a result of investigating the characteristics of the semiconductor laser device 51, a transparent threshold current density per quantum-well layer (kA/cm/well) at the temperature of 20° C. is as low as 0.11 to 0.13. In this manner, the semiconductor laser device 51 can lower the transparent threshold current density, and increase the quantum efficiency compared to the conventional semiconductor laser device.

Furthermore, the characteristic temperature T₀ (K) of the threshold current Iₜₕ at a temperature range between 25° C. and 85° C. is as high as 80 to 100. The absolute value of the characteristic temperature T₀ (K) (about 80 to 100) is large enough compared to the characteristic temperature of a GaInAsP semiconductor laser device fabricated on an InP substrate (i.e., the conventional semiconductor laser device) (50K to 70K), and will not cause any particular problem in terms of the temperature characteristics.

As described above, according to the second embodiment, the amount of band discontinuity in the conduction band between the barrier layer sandwiched by the quantum-well layers and the quantum-well layers is set to equal to or more than 26 meV and less than 300 meV, and the amount of band discontinuity in the conduction band between the outermost barrier layers and the quantum-well layers is set to equal to or more than 300 meV. Therefore, it is possible to bring out the same effect as the first embodiment, and realize a semiconductor laser device that can confine the carriers injected into the active layer in the quantum-well layers for sure.

A modification example of the second embodiment will be explained below. Although the semiconductor laser device 51 described in the second embodiment is a VCSEL, the present invention is not limited to the VCSEL. A semiconductor laser device according to the modification example of the second embodiment is an edge-emitting semiconductor laser device. In other words, the semiconductor laser device according to the modification example of the second embodiment has a structure in which the amount of band discontinuity ΔE_{c2} between the outermost barrier layers and the quantum-well layers of the semiconductor laser device 21 according to the modification example of the first embodiment is set to equal to or more than 300 meV, to suppress the overflow of the carriers to the outermost barrier layers.

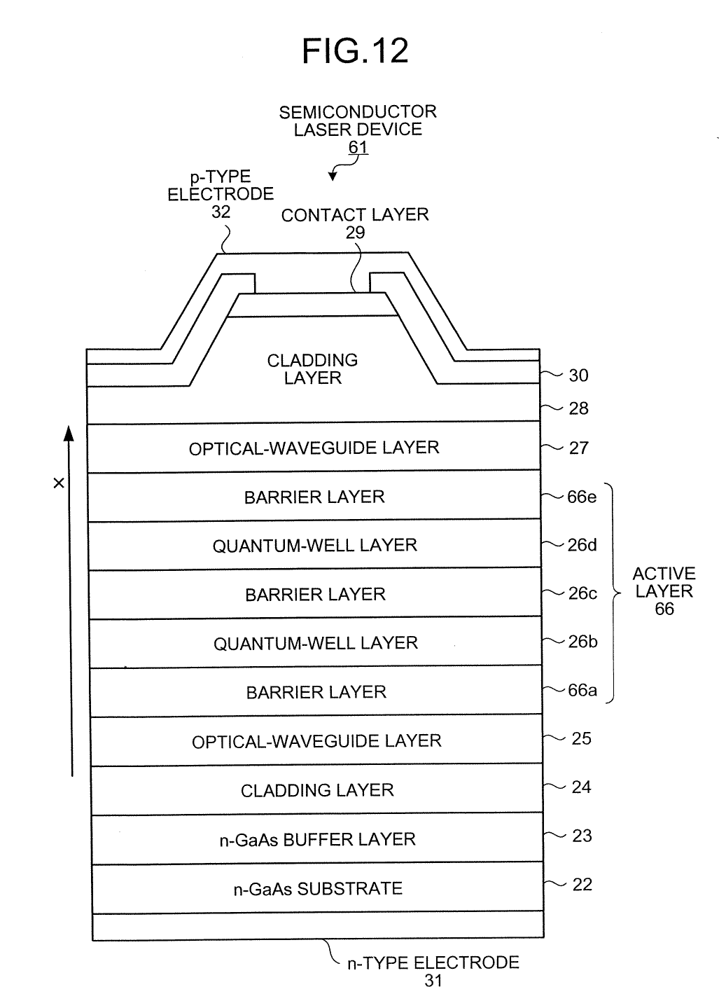

FIG. 12 is a cross section of a semiconductor laser device 61 according to the modification example of the second embodiment in a direction perpendicular to a light-emitting direction. As shown in FIG. 12, the semiconductor laser device 61 includes an active layer 66 instead of the active layer 26 of the semiconductor laser device 21 according to the modification example of the first embodiment. The active layer 66 includes outermost barrier layers 66a and 66e instead of the outermost barrier layers 26a and 26e of the semiconductor laser device 21. Other structures are the same as those of the modification example of the first embodiment, and the same reference numerals are allocated to the same component parts.

The barrier layers 66a and 66e confine the carriers injected into the active layer 66 in the quantum-well layers 26b and 26d, and suppresses an overflow of the carriers from the quantum-well layers 26b and 26d to the barrier layers 66a and 66e. The barrier layers 66a and 66e are the outermost barrier layers formed on both ends of the active layer 66 in the direction of the layer thickness, and are adjacent to the optical-waveguide layers 25 and 27, respectively. The barrier layers 66a and 66e are realized by, for example, uniform layers of compound semiconductors including GaNAs in the layer materials. The barrier layers 66a, 26c, and 66e can also be uniform layers of compound semiconductors including GaNAsP, GaInAs, GaInNAs, GaInAsSb, GaInNAsSb, or GaNAsSb in the layer materials, instead of GaNAs.

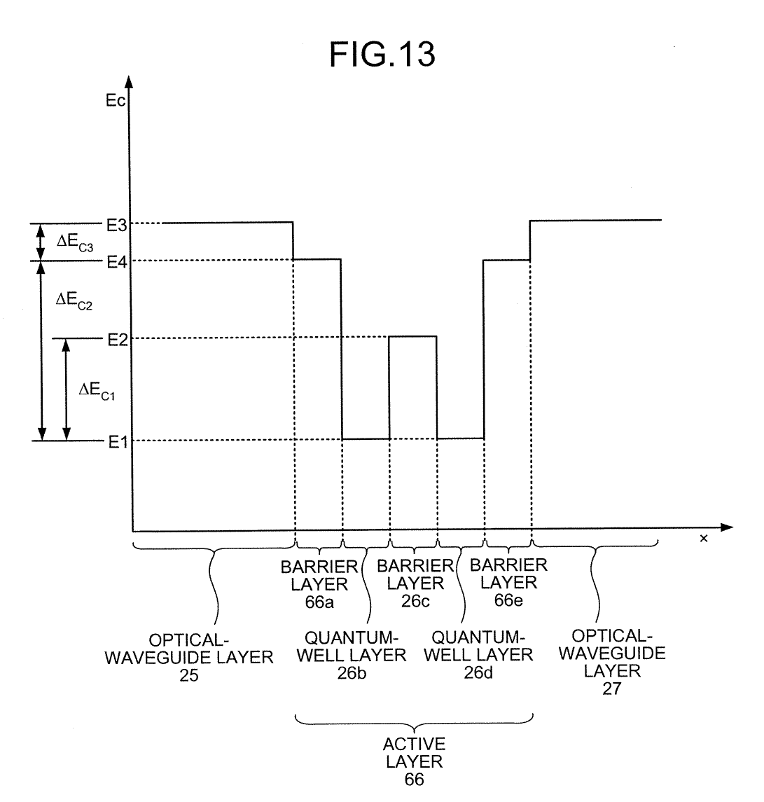

FIG. 13 is a band diagram for explaining an energy level profile of the optical-waveguide layers 25 and 27 and the active layer 66 in the conduction band. In the band diagram shown in FIG. 13, the direction of the layer thickness from the optical-waveguide layer 25 toward the optical-waveguide layer 27 is taken as the x-axis (see FIG. 12), and a profile of the energy level E_{c} in the conduction band is shown for a position in the direction of the layer thickness.

As shown in FIG. 13, an amount of strain, a layer thickness, and a composition of the layer materials of the barrier layers 66a and 66e are controlled so that the energy level E_{c} (meV) in the conduction band becomes E4. In this case, the amount of band discontinuity ΔE_{c2} between the outermost barrier layers 66a and 66e and the quantum-well layers 26b and 26d is set to equal to or more than 300 meV. The barrier layers 66a, and 66e satisfying the condition for the amount of band discontinuity ΔE_{c2} can bring out the carrier confining function in the quantum-well layers 26b and 26d, in the virtually same way as the case in the second embodiment, and suppress the overflow of the carriers from the quantum-well layers 26b and 26d to the barrier layers 66a and 66e.

Comparing FIG. 10 and FIG. 13, the profile of the energy level E_{c} of the semiconductor laser device 61 near the active layer 66, i.e., the energy level profile of the optical-waveguide layers 25 and 27 and the active layer 66 shown in FIG. 13 is virtually the same as that near the active layer 56 of the semiconductor laser device 51 according to the second embodiment. The profile of the energy level E_{c} near the active layer 66 is the one in which the cladding layers 5 and 7 shown in FIG. 10 are replaced by the optical-waveguide layers 25 and 27, the barrier layers 56a, 6c, and 56e shown in FIG. 10 are replaced by the barrier layers 66a, 26c, and 66e, and the quantum-well layers 6b and 6d shown in FIG. 10 are replaced by the quantum-well layers 26b and 26d.

Therefore, the semiconductor laser device 61 that has the above profile of the energy level E_{c} near the active layer 66 includes, as in the case of the semiconductor laser device 51 according to the second embodiment, the active layer 66 that is formed with the quantum-well layers 26b and 26d and the barrier layers 66a, 26c, and 66e satisfying the conditions for the amounts of band discontinuity ΔE_{c1} and ΔE_{c2} and the optical-waveguide layers 25 and 27 satisfying the condition for the amount of band discontinuity ΔE_{c3}. Therefore, the semiconductor laser device 61 can confine the carriers injected into the active layer 66 in the quantum-well layers 26b and 26d for sure, and make the carrier density uniform between the quantum-well layers 26b and 26d.

An amount of band discontinuity ΔE_{c3} between the optical-waveguide layers 25 and 27 and the barrier layers 66a and 66e of the semiconductor laser device 61 according to the modification example of the second embodiment can be a value with which the carriers can be injected into the active layer 66, preferably to be equal to or more than 26 meV. In this case, it is desired that the amount of band discontinuity ΔE_{c2} between the barrier layers 66a and 66e and the quantum-well layers 26b and 26d and the amount of band discontinuity ΔE_{c3} between the optical-waveguide layers 25 and 27 and the barrier layers 66a and 66e satisfy a condition that a some of the ΔE_{c2} and the ΔE_{c3} (ΔE_{c2}+ΔE_{c3}) is less than 800 meV. With this condition, the difference of the energy level E_{c} between the quantum-well layers 6b and 6d and the optical-waveguide layers 25 and 27 can be set to the same value as the case in the modification example of the first embodiment.

The semiconductor laser device 61 employing the above structure can make the density of the carriers injected into the active layer 66 uniform between the quantum-well layers 26b and 26d, in the virtually same way as the semiconductor laser device 51 according to the second embodiment, and confine the carriers injected into the active layer 66 in the quantum-well layers 26b and 26d for sure, which makes it possible to lower the threshold current Iₜₕ at the temperature of equal to or lower than 100° C., more particularly, at the operating temperature near the room temperature.

From a result of investigating the characteristics of the semiconductor laser device 61, a transparent threshold current density per quantum-well layer (kA/cm/well) at the temperature of 20° C. is as low as 0.11 to 0.13. In this manner, the semiconductor laser device 61 can lower the transparent threshold current density, and increase the quantum efficiency compared to the conventional semiconductor laser device.

Furthermore, the characteristic temperature T₀ (K) of the threshold current Iₜₕ at a temperature range between 25° C. and 85° C. is as high as 80 to 100. The absolute value of the characteristic temperature T₀ (K) (about 80 to 100) of the semiconductor laser device 61 is large enough compared to the characteristic temperature of a GaInAsP semiconductor laser device fabricated on an InP substrate (i.e., the conventional semiconductor laser device) (50K to 70K), and will not cause any particular problem in terms of the temperature characteristics.

As describe above, according to the modification example of the second embodiment, the layer structure is virtually the same as that of the modification example of the first embodiment, and because the energy level profile in the conduction band in an area near the active layer, i.e., a layer area where the active layer is sandwiched by two optical-waveguide layers, is set to virtually the same as that near the active layer according to the second embodiment, it is possible to realize an edge-emitting semiconductor laser device having the same effect as the second embodiment.

By employing a layer structure in which the active layer formed by arranging the quantum-well layers and the barrier layers satisfying the conditions of the amounts of band discontinuity in the conduction band, it is possible to emit a laser light, for example, in 1300-nm wavelength band, and lower the threshold current in a temperature range of equal to or lower than 100° C., more particularly, at the operating temperature near the room temperature.

Although two quantum-well layers are formed in the active layer according to the first and the second embodiments and the modification examples, the present invention is not limited to this scheme, but three or more quantum-well layers can be formed in the active layer. In this case, the quantum-well layers and the barrier layers are arranged alternatively in the active layer.

Furthermore, although the quantum-well layers are formed by uniform layers of compound semiconductors as the layer materials according to the first and the second embodiments and the modification examples, the present invention is not limited to this scheme, but the quantum-well layers in the active layer can include a quantum dot, and can be quantum-dot layers in which the quantum dots are arranged in a lattice structure.

In addition, although the oscillation wavelength of the laser light generated by the recombination of the carriers in the active layer is set to equal to or more than 1200 nm and equal to or less than 1350 nm according to the first and the second embodiments and the modification examples, the present invention is not limited to this scheme, but the oscillation wavelength of the laser light can be in a wavelength band, for example, in a range of 900 nm to 1650 nm.

Moreover, the ridge waveguide type VCSEL and edge-emitting laser having the MQW-SCH structure are used as examples according to the first and the second embodiments and the modification examples, the present invention is not limited to this scheme, but can be applied to a buried heterostructure (BH) type semiconductor laser device, a self alignment structure (SAS) type semiconductor laser device, or a semiconductor laser device having a decoupled confinement heterostructure, as long as the semiconductor laser device includes an active layer in which a plurality of quantum-well layers and a plurality of barrier layers are formed alternatively.

As describe above, according to an embodiment of the present invention, a carrier density between the quantum-well layers can be made uniform by intentionally performing a carrier overflow by a thermal excitation between the quantum-well layers. Therefore, it is possible to realize a semiconductor laser device with a capability of reducing the threshold current in a temperature range equal to or below 100 degrees Celsius, particularly in an operation temperature near the room temperature.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor laser device comprising:
an active layer including a plurality of quantum-well layers and a plurality of barrier layers, the active layer being formed by arranging the quantum-well layers and the barrier layers alternatively, wherein
an amount of band discontinuity in a conduction band between a barrier layer that is sandwiched by the quantum-well layers and the quantum-well layers is equal to or more than 26 milli-electron volts and less than 300 milli-electron volts.

2. The semiconductor laser device according to claim 1, further comprising:
a pair of cladding layers that sandwiches the active layer, wherein
an amount of band discontinuity in a conduction band between outermost barrier layers that is respectively adjacent to the cladding layers and the cladding layers is equal to or more than 250 milli-electron volts and equal to or less than 500 milli-electron volts.

3. The semiconductor laser device according to claim 1, wherein
an amount of band discontinuity in a conduction band between outermost barrier layers that are formed outermost sides of the active layer in a direction of layer thickness and the quantum well layers is equal to or more than 300 milli-electron volts.

4. The semiconductor laser device according to claim 1, wherein
the barrier layers include any one of GaNAs, GaNAsP, GaInAs, GaInNAs, GaInAsSb, GaInNAsSb, and GaNAsSb in layer materials.

5. The semiconductor laser device according to claim 1, wherein
the quantum-well layers include any one of GaInNAsSb, GaInAsSb, and GaInAs in layer materials.

6. The semiconductor laser device according to claim 1, wherein
an oscillation wavelength of a laser light generated in the active layer is in a range of equal to or more than 1200 nanometers and equal to or less than 1350 nanometers.

7. The semiconductor laser device according to claim 1, wherein
the semiconductor laser device is a vertical cavity surface-emitting laser device.
